(19) United States
(12) Patent Application Publication
(10) Pub. No.: US 2009/0321806 A1
(43) Pub. Date: Dec. 31, 2009

(54) NONVOLATILE MEMORY WITH FLOATING GATES WITH UPWARD PROTRUSIONS

(76) Inventors: Len Mei, San Jose, CA (US); Yue-Song He, San Jose, CA (US)

Correspondence Address: Haynes and Boone, LLP;IP Section, 2323 Victory Avenue, SUITE 700, Dallas, TX, 75219, US

(21) Appl. No.: 12/146,933

(22) Filed: Jun. 26, 2008

(51) Int. Cl. H01L 29/788; H01L 21/336

(52) U.S. Cl. 257/315; 438/257; 257/E29.3; 257/E21.409

(57) ABSTRACT

Substrate isolation regions (570) initially protrude upward above a semiconductor substrate (520) but are later etched down. Before they are etched down, floating gate layer (590) is deposited and etched or polished off the top surfaces of the substrate isolation regions. The floating gate layer thus has upward protrusions overlying sidewalls of the substrate isolation regions. When the substrate isolation regions are etched down, the floating gate layer's upward protrusions' outer sidewalls become exposed. The upward protrusions serve to increase the capacitance between the floating and control gates. The floating gates' bottom surfaces are restricted to the active areas (564) not to overlie the substrate isolation regions. Other features are also provided.

### BACKGROUND OF THE INVENTION

The present invention relates to integrated circuits, and more particularly to nonvolatile memories with floating gates.

A floating gate is a conductive element which stores charge defining the state of a memory cell. The state of the memory cell is changed by transferring electrons to or from the floating gate through a dielectric. For example, electrons can be transferred between the floating gate and the active area when a voltage is induced between the active area and a control gate. In enable use of a lower voltage, it is desirable to increase the capacitance between the floating and control gates relative to the capacitance between the floating gate and the active area. This relative capacitance is sometimes characterized as the “gate coupling ratio” which is the ratio of the capacitance between the floating and control gates to the total capacitance of the floating gate.

In times past, substrate isolation of the active area was accomplished by LOCOS. The floating gate overlapped the LOCOS isolation regions, and the control gate overlapped the floating gate. Hence, there was a large overlap between the floating and control gates relative to the overlap between the floating gate and the active area, resulting in a large gate coupling ratio. In a drive to reduce the memory area, LOCOS was replaced by shallow trench isolation (STI). The STI dielectric can be deposited to have well defined vertical protrusions rising above the active area. These protrusions allow the floating gate to be restricted to the active area rather than sprawling over the substrate isolation. Consequently, the gate coupling ratio suffers.

FIGS. 1A-1G illustrate a memory fabrication method which increases the gate coupling ratio by using spacers on the floating gate. This method is described in U.S. Pat. No. 6,171,909 B1 issued Jun. 9, 2001 to Ding et al. and incorporated herein by reference. A substrate 100 (FIG. 1A) is oxidized to form tunnel oxide 102. Conductive polysilicon 104 and then silicon nitride 106 are formed on oxide 102. Layers 106, 104, 102 and the substrate 100 are patterned using a photoresist mask (not shown) to form trenches 112 in substrate 100. Oxide liner 114 (FIG. 1B) and oxide 116 are formed to fill the trenches and cover the silicon nitride 106. Oxide 116 is polished by chemical mechanical polishing (CMP). The CMP stops on nitride 106 (FIG. 1C). Layers 114, 116 provide shallow trench isolation (STI), and are shown collectively as 118 in FIGS. 1D-1G.

Oxide 118 is etched down (FIG. 1D) to expose the upper portions of polysilicon features 104. Doped polysilicon 120 (FIG. 1E) is deposited and anisotropically etched to expose the oxide 118 (FIG. 1F). This etch forms spacers 120a on the sidewalls of each polysilicon feature 104 and the overlying nitride feature 106. Each feature 104 and the adjacent spacers 120a provide a conductive feature 122. Features 122 will provide floating gates.

Nitride 106 is removed. Dielectric 124 (FIG. 1G), which can be ONO (oxide/nitride/oxide), and then doped polysilicon 126 are deposited over substrate 100. Layers 126, 124, 122 are patterned to form floating gates from layer 122 and control gates from layer 126.

Spacers 120a increase the gate coupling ratio.

FIGS. 2A-2D illustrate another process, described in U.S. Pat. No. 6,537,880 B1 issued Mar. 25, 2003 to Tseng, incorporated herein by reference. P type monocrystalline silicon substrate 1 (FIG. 2A) is processed to form STI regions 2. More particularly, STI trenches are defined photolithographically and then etched in substrate 1, then are filled with silicon oxide. The oxide is planarized by CMP. The substrate is cleaned, and tunnel dielectric 3 (silicon dioxide) is thermally grown on the substrate.

Doped polysilicon 4a is deposited. Then silicon nitride 5 is deposited and patterned photolithographically to form nitride features 5 over areas located between STI regions 2. Doped polysilicon 6a is conformally deposited and etched anisotropically to leave spacers 6b (FIG. 2B) on the sidewalls of nitride features 5. Then an anisotropic etch of polysilicon removes exposed polysilicon 4a over STI regions 2 (FIG. 2C). The polysilicon spacers 6b (shown at 6c in FIG. 2C) are reduced in height. The polysilicon spacers 6c and polysilicon 4a will provide the floating gates.

Nitride 5 is removed. A layer 7 (FIG. 2D) of NO (oxidized silicon nitride) or ONO and doped polysilicon 8 are deposited and patterned as needed.

### SUMMARY

This section summarizes some features of the invention. Other features may be described in the subsequent sections. The invention is defined by the appended claims, which are incorporated into this section by reference.

In some embodiments of the present invention, a floating gate has upward protrusions similar to the spacers of FIGS. 1G and 2D, but the floating gate is manufactured by a different method, possibly (but not necessarily) from a single polysilicon layer. Also, in some embodiments, the floating gate's bottom surface does not overlie the substrate isolation regions (e.g. the STI regions). Thus, the floating gate's bottom surface can be restricted to the active area. In some embodiments, this geometry allows reducing the width of the substrate isolation regions and hence reducing the memory size.

More particularly, the memory fabrication may start with fabricating the STI regions, i.e. by etching trenches in a semiconductor substrate using a suitable mask (possibly a hard mask) lying over the active areas. The trenches are filled with dielectric, e.g. silicon oxide. This STI dielectric initially covers the mask layer, but then the STI dielectric is polished by CMP to provide a top surface level with the mask's top surface. Later, the STI dielectric will be etched down to its final thickness. However, before this etch, the mask is removed from over the active areas, the tunnel dielectric is formed on the active areas, and then a floating gate layer is deposited. The floating gate layer goes up over the STI dielectric and down over the active areas. The floating gate layer thus has upward protrusions over the sidewalls of the STI dielectric.

The floating gate layer's portions are removed from over the STI dielectric (e.g. by CMP). Then the STI dielectric is etched down to its final thickness. This etch exposes the floating gate layer's protrusions' sidewalls on the side of the STI dielectric. The resulting structure is similar to that of FIG. 1F but the floating gate layer's protrusions' bottom surface is restricted to the active area rather than overlying the STI dielectric (see e.g. FIG. 5G described in more detail below). The remaining steps can be as described above in connection with FIG. 1G.

The invention is not limited to the embodiments or advantages discussed in this section or shown in FIG. 5G except as defined by the appended claims.

### BRIEF DESCRIPTION OF THE DRAWINGS

FIGS. 1A-1G, 2A-2D illustrate prior art nonvolatile memories at different stages of fabrication.

FIG. 3 is a circuit diagram of a memory array implemented using some embodiments of the present invention.

FIG. 4 is a top view of some features of the array of FIG. 3.

FIGS. 5A-5G, 6, 7 illustrate vertical cross sections of nonvolatile memories at different stages of fabrication according to some embodiments of the present invention.

### DESCRIPTION OF SOME EMBODIMENTS

The embodiments described in this section illustrate but do not limit the invention. For example, the invention is not limited to particular materials, dimensions, or fabrication processes except as defined by the appended claims.

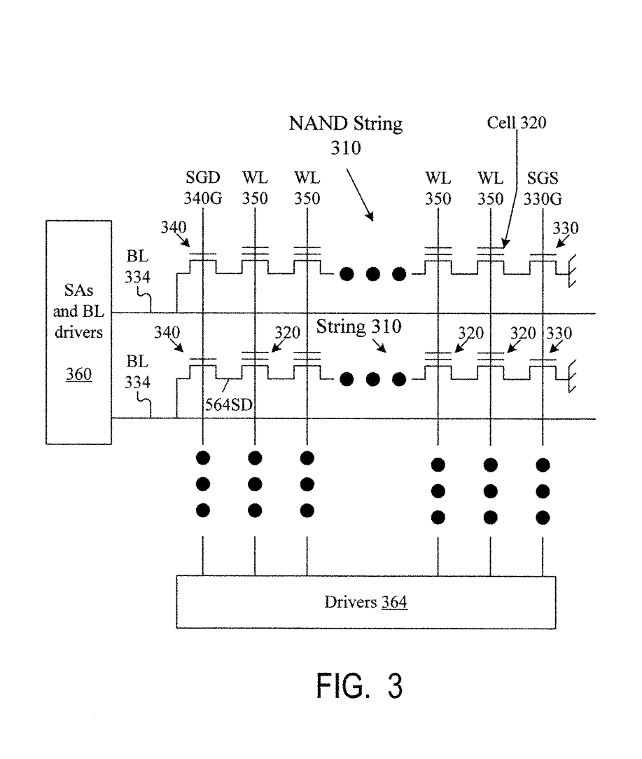

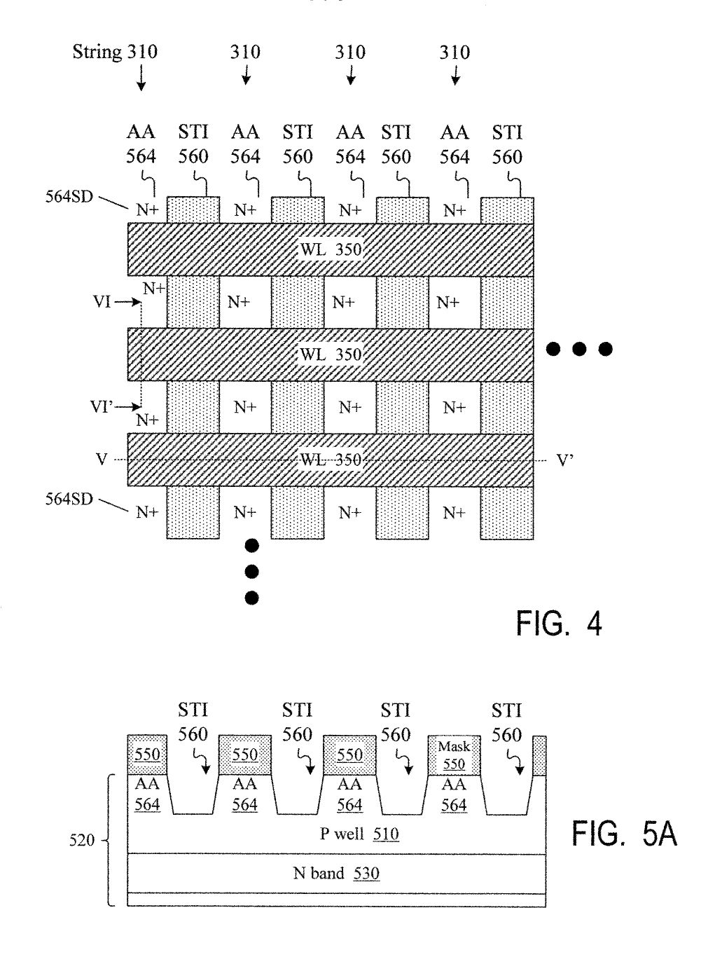

Some embodiments of the present invention will now be described on the example of a NAND memory array whose circuit diagram is shown in FIG. 3 and the top view is shown in FIG. 4. The memory array includes a number of NAND strings 310. Each string 310 includes a number (e.g. 32) of serially connected memory cells 320. One end of each string is connected to a ground voltage through a respective select transistor 330. The other end of each string is connected to a respective bitline 334 through a respective select transistor 340. Each of transistors 330, 340 is connected to a single string 310. Each bitline 334 may be connected to multiple strings 310. The control gate of each memory cell 320 is provided by a corresponding wordline 350. The gate of transistor 330 is provided by a corresponding source-side select gate line (SGS) 330G. The gate of transistor 340 is provided by a corresponding drain-side select gate line (SGD) 340G. The NAND memory array is organized as a number of blocks. Each block has multiple strings 310 which share the wordlines 350, an SGS line 330G, and an SGD line 340G. Each wordline provides the control gate to one memory cell in each string in the block. The bitlines 334 are connected to sense amplifiers and drivers 360. The wordlines 350 and the select gate lines 330G, 340G are connected to drivers 364. FIG. 4 is the top view of a portion of one block.

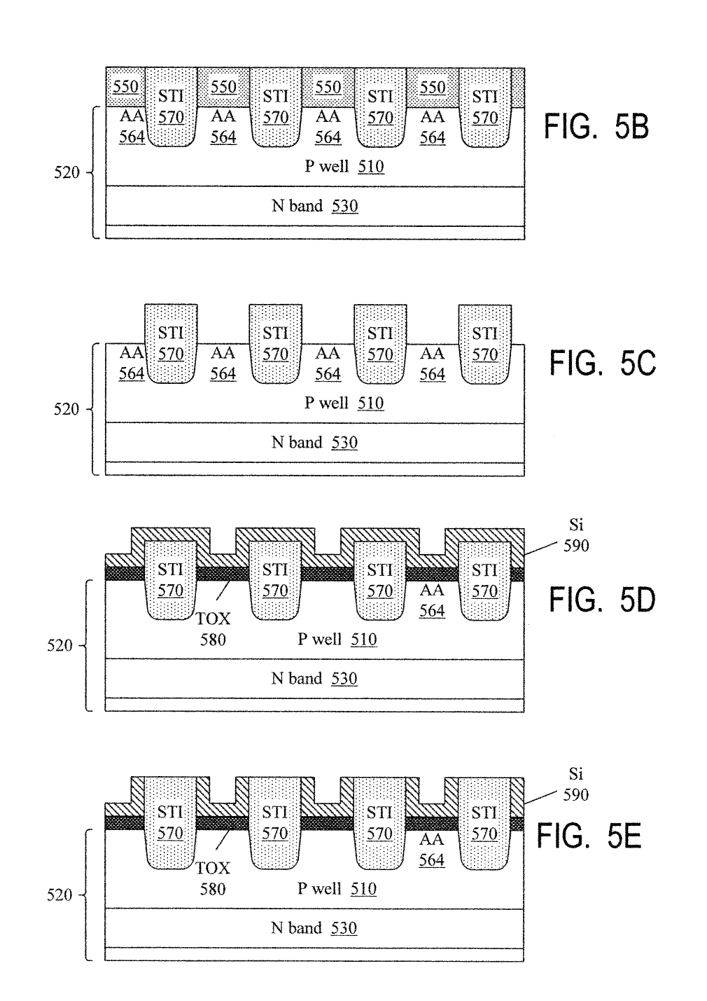

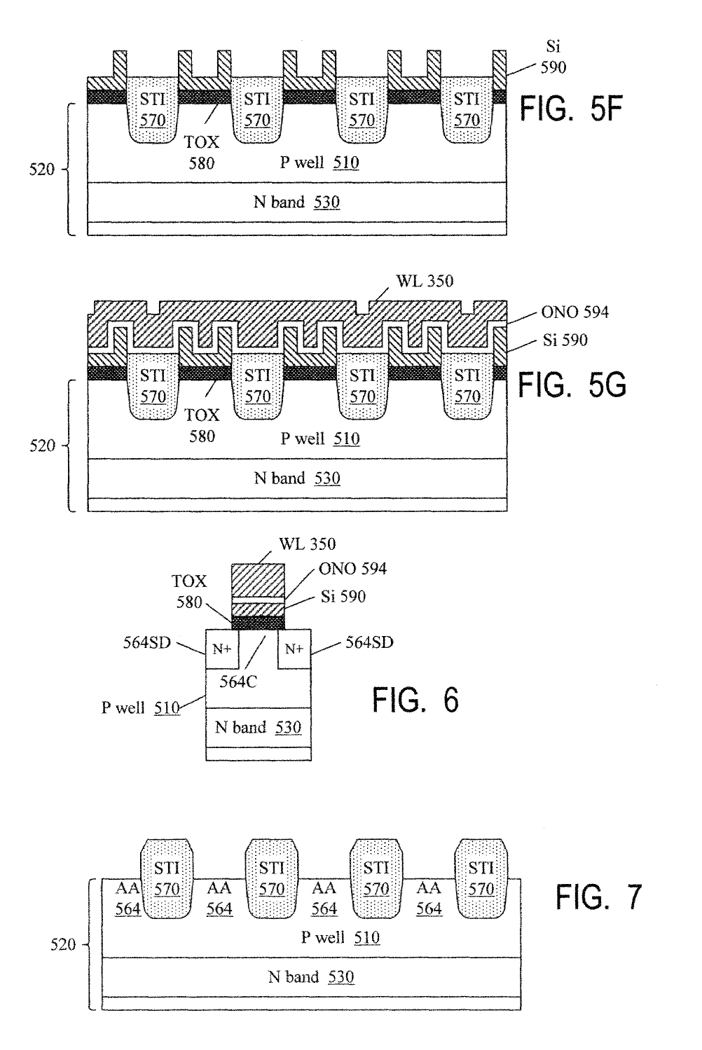

FIGS. 5A-5G show vertical cross sections through a wordline 350 at different stages of fabrication. The cross sectional plane is marked V-V′ in FIG. 4. The memory block is fabricated in a P type well 510 of a semiconductor substrate 520 (e.g. monocrystalline silicon). The P well 510 is isolated below by an N type band region 530 in substrate 520, and may be isolated on the sides by N type regions or in some other way. P well 510, N type band region 530, and the N type regions on the sides of P well 510 can be charged to suitable voltages by drivers 364. These and other particulars are not limiting except as defined by the appended claims.

A mask 550 is formed on substrate 520 to define STI trenches 560 and active areas 564 (see also FIG. 4). Each STI trench 560 and each active area 564 runs in the bitline direction (i.e. perpendicular to the wordlines) through the memory block. Each active area 564 includes the active areas of all the memory cells of a respective string 310. In some embodiments, mask 550 is a hard mask (e.g. a pad layer of silicon oxide and an overlying layer of silicon nitride). The mask can be patterned photolithographically.

STI trenches 560 are then etched in substrate 520 while the mask 550 protects the active areas. Trenches 560 are filled with dielectric (e.g. silicon oxide) 570 as shown in FIG. 5B. The dielectric 570 may initially cover the mask 550 but may then be etched or polished down (by CMP for example) to provide a planar top surface which is level with the top surface of mask 550. Other processes may also be used. For example, the top surface of STI dielectric 570 may be recessed below the top surface of mask 550.

Mask 550 is removed (FIG. 5C). Tunnel dielectric 580 (FIG. 5D) is formed on the active areas 564. In some embodiments, tunnel dielectric 580 is silicon dioxide (marked as “TOX”, i.e. tunnel oxide) thermally grown to a suitable thickness (e.g. 9 nm).

Doped polysilicon 590 is deposited over the structure. This layer will provide the floating gates. In some embodiments, polysilicon 590 is a conformal layer. The top surface of polysilicon 590 is depressed over the active areas. In some embodiments, the distance between the adjacent STI trenches 560 is 200 nm; the height of each STI region 570 above the substrate 520 (i.e. the thickness of mask 550) is 150 nm; the thickness of polysilicon 590 is 25 nm; and the thickness of tunnel dielectric 580 is 9 nm. Thus, polysilicon 590 goes up and down over the STI dielectric 570.

As shown in FIG. 5E, portions of polysilicon 590 are removed to expose STI dielectric 570. This can be done by chemical mechanical polishing, or by depositing a suitable material (e.g. photoresist) with a planar top surface and then etching the material to expose the polysilicon 590 over the STI dielectric 570 but not over the active areas. The exposed polysilicon can then be removed to provide the structure of FIG. 5E. In either case, no masking is needed over the memory block. At the active areas' edges adjacent to STI dielectric 570, the polysilicon 590 has upward protrusions overlaying the sidewalls of the STI dielectric 570.

STI dielectric 570 is then etched down (FIG. 5F) to its final thickness. The etch can be selective to polysilicon, so no masking is needed over the memory block. In some embodiments, the etch stops when the top surface of dielectric 570 is above the top surface of tunnel dielectric 580 so that the tunnel dielectric 580 is not exposed.

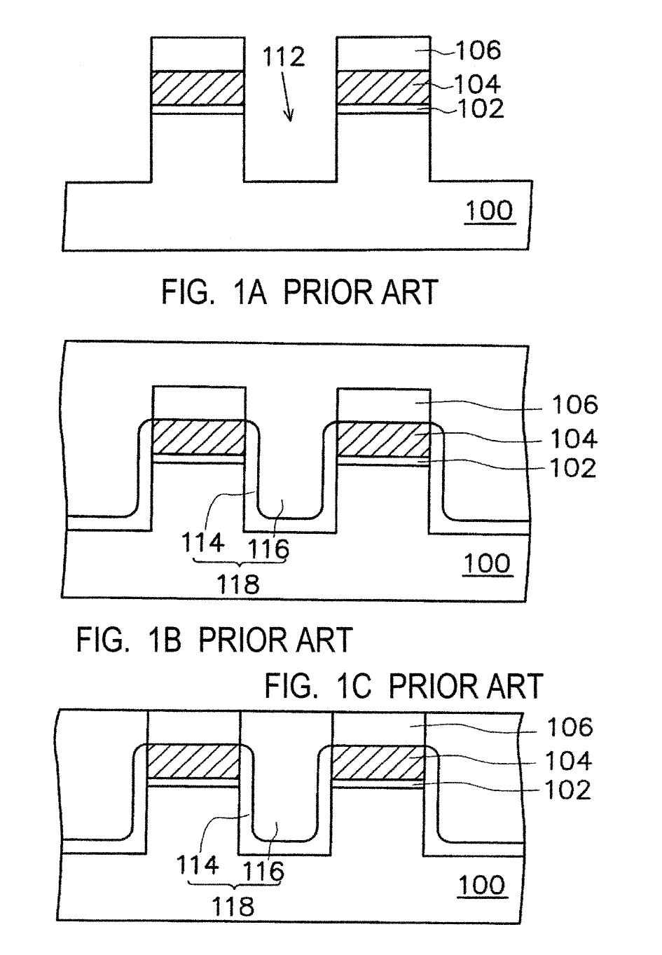

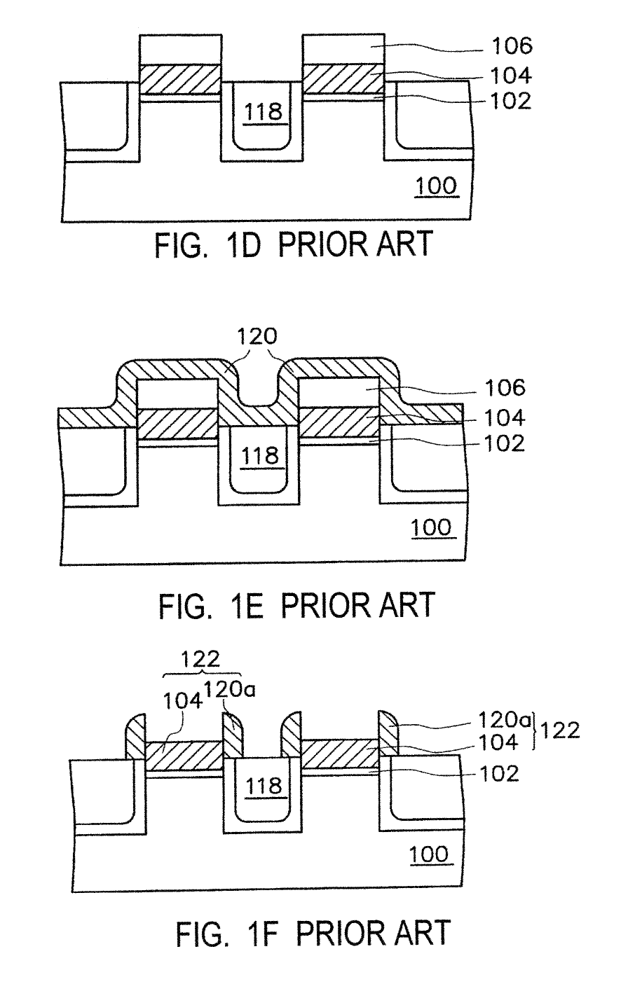

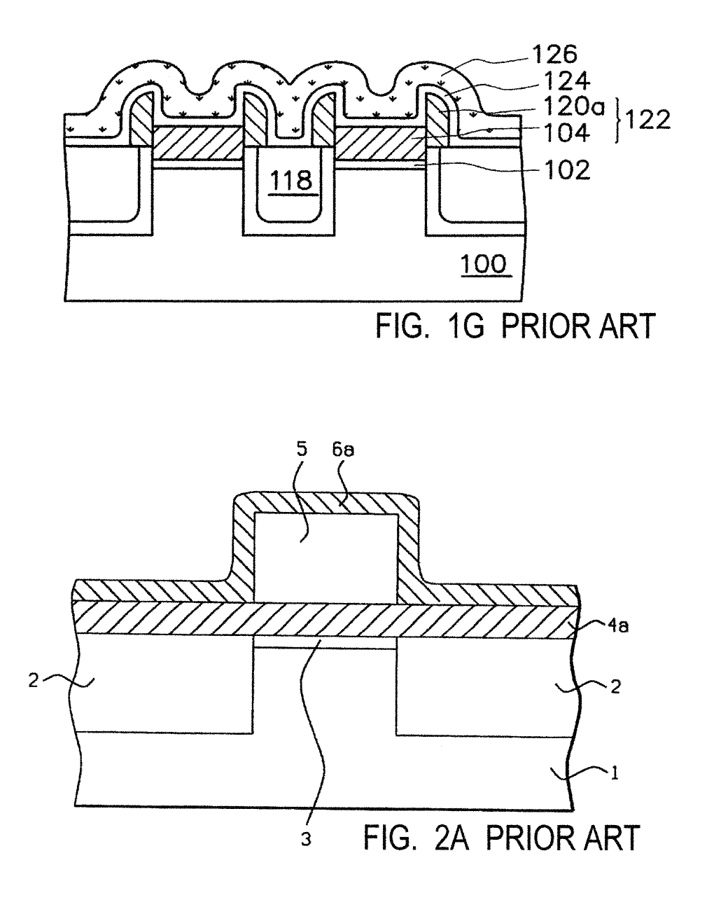

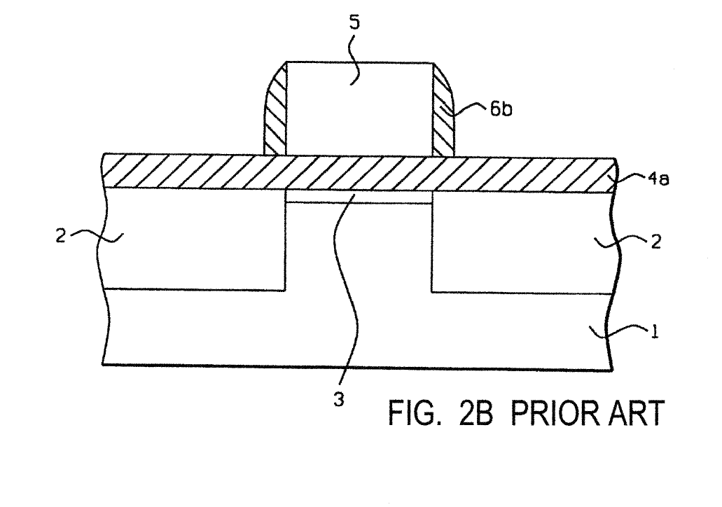

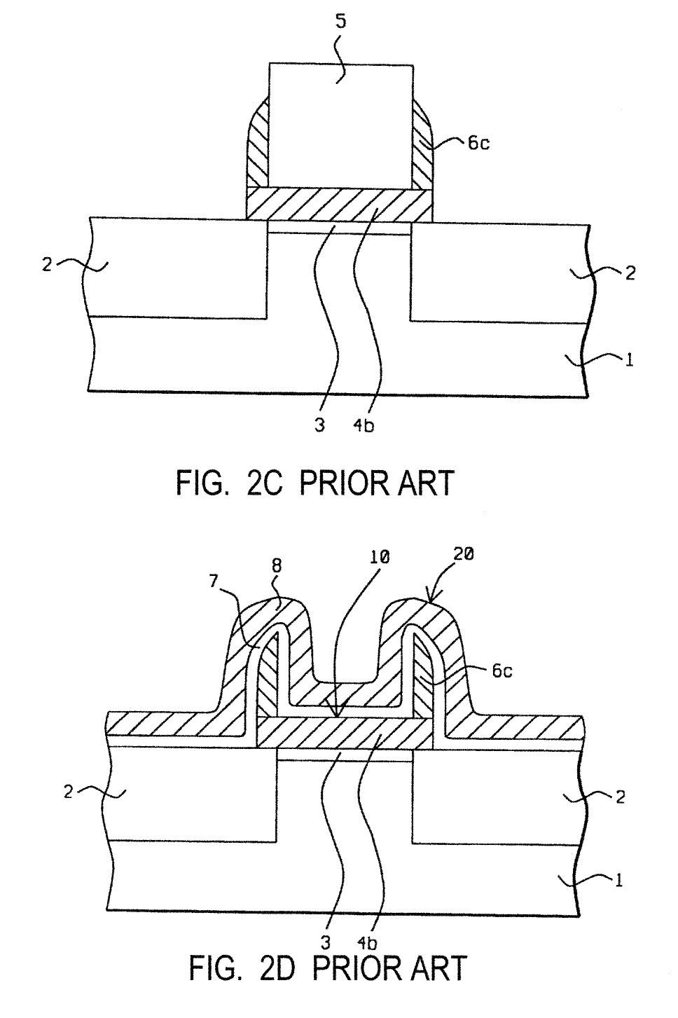

The next steps can be similar to those described above in connection with FIG. 1G or 2D. Thus, in the embodiment of FIG. 5G, suitable dielectric 594 (e.g. a stack of silicon dioxide, silicon nitride, silicon dioxide) is deposited over the structure, to an exemplary thickness of 13 to 15 nm. Dielectric 594 can be conformal. Conductive material 350 (e.g. doped polysilicon, polycide, metal, or nanocarbon) is deposited on dielectric 594 to provide the wordlines. The bottom surface of conductor 350 has a conformal profile over upward protrusions of floating gate layer 590 to increase the capacitance between the floating and control gates. Layers 350, 594, 590 are patterned, possibly using a single photo-masking step, to define the wordlines 350 as in FIG. 4 and to etch away the polysilicon 590 between the wordlines. An N type dopant is implanted into substrate 520 to form N+ source/drain regions 564SD (FIGS. 4, 6) which are part of active areas 564. FIG. 6 shows the cross section “VI-VI” (marked in FIG. 4) passing through the middle of active area 564. Channel regions 564C (FIG. 6) are the P type active area portions located under the floating gates between the source/drain regions 564D. Bitlines 334 (FIG. 3) and other features are formed using known techniques.

Each memory cell can be programmed by tunneling of electrons from the cell's channel region 564C and/or source/drain region or regions 564SD into the floating gate 590 as the channel and/or source/drain region or regions are provided with a negative voltage relative to control gate 350 (i.e. the wordline). The memory cell can be erased by the reverse transfer of electrons as the channel and/or source/drain region or regions are provided with a positive voltage relative to control gate 350. The memory cell is read by sensing the channel current when the cell's source/drain regions are at different voltages and the control gate 350 is at a positive voltage relative to at least one of the source/drain regions. The NAND reading, programming and erasing techniques are well known. See e.g. W. D. Brown et al., Nonvolatile Semiconductor Memory Technology (Institute of Electrical and Electronics Engineers, Inc. 1998), section 4.4.5, pages 241-244, incorporated herein by reference. The invention is not limited to NAND arrays however. The memory cell can be part of NOR or other arrays, and can be programmed and/or erased by hot carrier injection for example. Some embodiments are one-time programmable (non-erasable) devices. Further, the invention is not limited to stacked-gate memory cells as in FIG. 6. For example, control gate 350 may overlap a source/drain region 564SD, or a separate select gate may be provided, to obtain split-gate architecture. A floating gate 590 may be part of a memory cell with multiple floating gates.

The invention is not limited to the embodiments described above. For example, tunnel dielectric 580 can be at least partially formed before the etch of STI trenches 560. Also, after at least partial removal of mask 550 (FIGS. 5B, 5C), STI dielectric 570 can be etched laterally to recess the top portions of the dielectric's sidewalls to facilitate deposition of polysilicon 590 and ONO 594. The resulting structure is shown in FIG. 7. See e.g. U.S. patent application Ser. No. 11/102,329 filed Apr. 7, 2005 by Chia-Shun Hsiao et al. and published as no. 2005-0196913 A1 on Sep. 8, 2005, incorporated herein by reference. In this case, the tops of the upward protrusions of floating gates 590 may overlie the STI dielectric 570. Whether or not the lateral etch of dielectric 570 is performed, it is possible for the floating gates 590 to lie entirely over the active areas 564. In some embodiments, the bottom surface of each floating gate 590 lies entirely over the corresponding active area 564. In some embodiments, each floating gate 590 has a bottom portion which is as thick as the thickness of polysilicon film 590 over the middle of the active area (e.g. 25 nm thick with the dimensions given above) and which lies entirely over the active area.

The invention is not limited to STI isolation. For example, STI trenches 560 can be omitted and/or replaced or combined with other isolation types (e.g. N type diffusion regions). Dielectric 570 can be replaced with a non-dielectric material and can be entirely removed at the stage of FIG. 5E. If STI isolation is used, material 570 can be removed at the stage of FIG. 5F and another dielectric can be deposited instead. Other embodiments and variations are within the scope of the invention as defined by the appended claims.

Some embodiments provide a method for fabricating an integrated circuit comprising one or more active areas of one or more nonvolatile memory cells each of which has one or more floating gates, the active areas being part of a semiconductor region (e.g. of P well 510), the method comprising: forming one or more first regions (e.g. STI dielectric 570 or non-dielectric features as explained above) which protrude upward from the semiconductor region, each first region having a sidewall adjacent to an edge of a corresponding one of the one or more active areas, the sidewall facing the corresponding active area; forming a first dielectric (e.g. tunnel dielectric 580) on the one or more active areas, wherein each said sidewall of each first region protrudes upward above the first dielectric at the edge of the corresponding active area; forming a first conductive layer (e.g. 590 as in FIG. 5E) on the first dielectric and over a part but not all of each first region, wherein at each said edge of each said active area, the first conductive layer has an upward protrusion overlaying the corresponding sidewall of the first region, the upward protrusion having a first sidewall facing the first dielectric region and having a second sidewall facing the active area; removing at least a portion of each first region (e.g. as in FIG. 5F) to expose the first sidewall of each said upward protrusion of the first conductive layer; forming a second dielectric (e.g. 594) on the first conductive layer, the second dielectric overlaying and contacting the first and second sidewalls of each said upward protrusion of the first conductive layer; and forming one or more conductive gates (e.g. provided by wordline 350) each of which overlays and physically contacts the second dielectric over the first and second sidewalls of each said upward protrusion of the first conductive layer.

In some embodiments, each floating gate is provided in its entirety by the first conductive layer.

In some embodiments, the second dielectric has a uniform thickness over the first and second sidewalls of each said upward protrusion. For example, the dielectric 594 may be ONO of a uniform thickness of 13 nm.

Some embodiments provide an integrated circuit comprising: a semiconductor region comprising an active area of a nonvolatile memory cell, the active area comprising a channel region having an edge extending along the channel region (e.g. the edge adjacent to the edge of STI trench 560); a first dielectric (e.g. 580) physically contacting the channel region; a floating gate physically contacting the first dielectric and separated by the first dielectric from the channel region, the floating gate's entire bottom surface being in physical contact with the first dielectric and/or overlying the active area, the floating gate comprising an upward protrusion at the edge of the channel region, the upward protrusion comprising a first sidewall facing outside of the channel region and a second sidewall opposite to the first sidewall and facing inside the channel region; a second dielectric (e.g. 594) overlaying the floating gate, the second dielectric overlaying and contacting the first and second sidewalls of the upward protrusion of the floating gate, the second dielectric having an upward protrusion over the upward protrusion of the floating gate, the upward protrusion of the second dielectric having a first sidewall overlaying the first dielectric over the upward protrusion of the floating gate and having a second sidewall overlaying the second sidewall of the upward protrusion of the floating gate; and a conductive gate overlaying and physically contacting the first and second sidewalls of the upward protrusion of the second dielectric.

The invention is defined by the appended claims.

1. A method for fabricating an integrated circuit comprising one or more active areas of one or more nonvolatile memory cells each of which has one or more floating gates, the active areas being part of a semiconductor region, the method comprising:
forming one or more first regions which protrude upward from the semiconductor region, each first region having a sidewall adjacent to an edge of a corresponding one of the one or more active areas, the sidewall facing the corresponding active area;
forming a first dielectric on the one or more active areas, wherein each said sidewall of each first region protrudes upward above the first dielectric at the edge of the corresponding active area;
forming a first conductive layer on the first dielectric and over a part but not all of each first region, wherein at each said edge of each said active area, the first conductive layer has an upward protrusion overlaying the corresponding sidewall of the first region, the upward protrusion having a first sidewall facing the first dielectric region and having a second sidewall facing the active area;
removing at least a portion of each first region to expose the first sidewall of each said upward protrusion of the first conductive layer;
forming a second dielectric on the first conductive layer, the second dielectric overlaying and contacting the first and second sidewalls of each said upward protrusion of the first conductive layer; and
forming one or more conductive gates each of which overlays and physically contacts the second dielectric over the first and second sidewalls of each said upward protrusion of the first conductive layer;
wherein each said floating gate comprises at least portions of the first and second sidewalls of each said upward protrusion of the first conductive layer.

2. The method of claim 1 wherein each floating gate is provided in its entirety by the first conductive layer.

3. The method of claim 1 wherein each first region is a dielectric region.

4. The method of claim 3 wherein each first region is an isolation region providing isolation for the adjacent active area.

5. The method of claim 1 wherein the one or more first regions comprise at least two regions whose respective sidewalls are adjacent to respective opposite edges of at least one said active area, and the first conductive layer has two of said upward protrusions at the respective opposite edges, each of said two of said upward protrusions' first and second sidewalls comprising a portion of one of said floating gates.

6. The method of claim 1 wherein the second dielectric has a uniform thickness over the first and second sidewalls of each said upward protrusion.

7. The method of claim 1 wherein the first conductive layer is initially formed to overlie all of each first region but then a portion of the first conductive layer is removed over each first region.

8. The method of claim 7 wherein the portion of the first conductive layer is removed over each first region by chemical mechanical polishing.

9. An integrated circuit comprising:
a semiconductor region comprising an active area of a nonvolatile memory cell, the active area comprising a channel region having an edge extending along the channel region;
a first dielectric physically contacting the channel region;
a floating gate physically contacting the first dielectric and separated by the first dielectric from the channel region, the floating gate's entire bottom surface overlying the active area, the floating gate comprising an upward protrusion at the edge of the channel region, the upward protrusion comprising a first sidewall facing outside of the channel region and a second sidewall opposite to the first sidewall and facing inside the channel region;
a second dielectric overlaying the floating gate, the second dielectric overlaying and contacting the first and second sidewalls of the upward protrusion of the floating gate, the second dielectric having an upward protrusion over the upward protrusion of the floating gate, the upward protrusion of the second dielectric having a first sidewall overlaying the first dielectric over the upward protrusion of the floating gate and having a second sidewall overlaying the second sidewall of the upward protrusion of the floating gate; and
a conductive gate overlaying and physically contacting the first and second sidewalls of the upward protrusion of the second dielectric.

10. The integrated circuit of claim 9 wherein the entire floating gate overlies the active area.

11. The integrated circuit of claim 9 wherein each upward protrusion of the floating gate is adjacent to a substrate isolation region.

12. The integrated circuit of claim 11 wherein each substrate isolation region is a dielectric region extending into the semiconductor region below a top surface of the channel region.

13. The integrated circuit of claim 10 wherein said upward protrusion of the floating gate is one of two upward protrusions of the floating gate at opposite edges of the channel region, each upward protrusion comprising a first sidewall facing outside of the channel region and a second sidewall opposite to the first sidewall and facing inside the channel region;
where the second dielectric overlays and contacts the first and second sidewalls of each upward protrusion of the floating gate, the second dielectric having an upward protrusion over each upward protrusion of the floating gate, each upward protrusion of the second dielectric having a first sidewall overlaying the first dielectric over the respective upward protrusion of the floating gate and having a second sidewall overlaying the second sidewall of the upward protrusion of the floating gate; and
the conductive gate overlays and physically contacts the first and second sidewalls of each upward protrusion of the second dielectric.

14. The integrated circuit of claim 10 wherein the second dielectric has a uniform thickness over the first and second sidewalls of the upward protrusion of the floating gate.

15. An apparatus comprising the integrated circuit of claim 10, the apparatus comprising circuitry for providing a voltage difference between the conductive gate and the semiconductor region to cause a charge transfer through the first dielectric to change a charge on the floating gate, the circuitry being at least partially inside the integrated circuit.

16. A method for operating the integrated circuit of claim 10, the method comprising providing a voltage difference between the conductive gate and the semiconductor region to cause a charge transfer through the first dielectric to change a charge on the floating gate.

17. An integrated circuit comprising:
a semiconductor region comprising a channel region of a nonvolatile memory cell, the channel region having an edge extending along the channel region;
a first dielectric physically contacting the channel region;
a floating gate physically contacting the first dielectric and separated by the first dielectric from the channel region, the floating gate's entire bottom surface being in physical contact with the first dielectric, the floating gate comprising an upward protrusion at the edge of the channel region, the upward protrusion comprising a first sidewall facing outside of the channel region and a second sidewall opposite to the first sidewall and facing inside the channel region;
a second dielectric overlaying the floating gate, the second dielectric overlaying and contacting the first and second sidewalls of the upward protrusion of the floating gate, the second dielectric having an upward protrusion over the upward protrusion of the floating gate, the upward protrusion of the second dielectric having a first sidewall overlaying the first dielectric over the upward protrusion of the floating gate and having a second sidewall overlaying the second sidewall of the upward protrusion of the floating gate; and
a conductive gate overlaying and physically contacting the first and second sidewalls of the upward protrusion of the second dielectric.

18. The integrated circuit of claim 17 wherein each upward protrusion of the floating gate is adjacent to a substrate isolation region.

19. The integrated circuit of claim 18 wherein each substrate isolation region is a dielectric region extending into the semiconductor region below a top surface of the channel region.

20. The integrated circuit of claim 17 wherein said upward protrusion of the floating gate is one of two upward protrusions of the floating gate at opposite edges of the channel region, each upward protrusion comprising a first sidewall facing outside of the channel region and a second sidewall opposite to the first sidewall and facing inside the channel region;
where the second dielectric overlays and contacts the first and second sidewalls of each upward protrusion of the floating gate, the second dielectric having an upward protrusion over each upward protrusion of the floating gate, each upward protrusion of the second dielectric having a first sidewall overlaying the first dielectric over the respective upward protrusion of the floating gate and having a second sidewall overlaying the second sidewall of the upward protrusion of the floating gate; and
the conductive gate overlays and physically contacts the first and second sidewalls of each upward protrusion of the second dielectric.

21. The integrated circuit of claim 17 wherein the second dielectric has a uniform thickness over the first and second sidewalls of the upward protrusion of the floating gate.

22. An apparatus comprising the integrated circuit of claim 17, the apparatus comprising circuitry for providing a voltage difference between the conductive gate and the semiconductor region to cause a charge transfer through the first dielectric to change a charge on the floating gate, the circuitry being at least partially inside the integrated circuit.

23. A method for operating the integrated circuit of claim 17, the method comprising providing a voltage difference between the conductive gate and the semiconductor region to cause a charge transfer through the first dielectric to change a charge on the floating gate.
